(19) United States
(12) Patent Application Publication
(10) Pub. No.: US 2025/0063641 A1
(43) Pub. Date: Feb. 20, 2025

(54) MICROWAVE ANNEALER FOR SEMICONDUCTOR WAFERS

(71) Applicant: Cornell University, Ithaca, NY (US)

(72) Inventors: James C. M. Hwang, Princeton Jct, NJ (US); Mohammad Javad Asadi, Ithaca, NY (US); Gianluca Fabi, Ithaca, NY (US); Chandrashekhar P. Savant, Ithaca, NY (US)

(21) Appl. No.: 18/929,485

(22) Filed: Oct. 28, 2024

Related U.S. Application Data
(63) Continuation-in-part of application No. PCT/US23/20415, filed on Apr. 28, 2023.
(60) Provisional application No. 63/337,039, filed on Apr. 29, 2022.
(60) Provisional application No. 63/341,129, filed on May 12, 2022.

(51) Int. Cl. H05B 6/72; H01L 21/324; H01L 21/66; H01L 21/67; H05B 6/68

(52) U.S. Cl. CPC H05B 6/72; H01L 21/324; H01L 21/67115; H01L 21/67248; H01L 22/12; H05B 6/68

(57) ABSTRACT

Technologies for microwave annealing include a chamber, a heating device configured to heat a substrate borne within the chamber during system operation, a microwave source configured to direct microwave energy at a predetermined frequency to a location within the chamber at which the substrate is disposed, and an elongated waveguide disposed within the chamber and extending between the microwave source and the location within the chamber at which the substrate is disposed. The substrate may be a semiconductor doped by ion implantation or epitaxial growth. During operation, the microwave energy activates a dopant and/or breaks up a defect cluster within the substrate.

### CROSS-REFERENCE TO RELATED APPLICATIONS

This application is a continuation-in-part of PCT International Application No. PCT/US2023/20415, entitled “MICROWAVE ANNEALER FOR SEMICONDUCTOR WAFERS,” which was filed on Apr. 28, 2023, which claims the benefit of and priority to U.S. Patent Application No. 63/337,039, entitled “MICROWAVE ANNEALER FOR SEMICONDUCTOR WAFERS,” which was filed on Apr. 29, 2022, and to U.S. Patent Application No. 63/341,129, entitled “MICROWAVE ANNEALER FOR SEMICONDUCTOR WAFERS,” which was filed on May 12, 2022, each of which is incorporated herein by reference in its entirety.

### BACKGROUND

In shrinking the size of semiconductor devices, their free-electron concentration typically must also be raised higher through heavy doping of the semiconductor material with impurities, as well as carefully controlled annealing to activate the impurities into effective donors of free electrons. Traditionally, doping is through ion implantation and activation is through thermal annealing. However, for scaling beyond the 3-nm node, the introduction of 3D nanostructure transistors such as nanowire and nanosheet MOSFETs may present new challenges for doping and activation. For example, the source and drain of these MOSFETs may be doped with more than 3×10²¹ P/cm³, an order of magnitude higher than the equilibrium solubility of P in silicon, through in situ doping during epitaxial growth instead of ion implantation. Although this helps reduce the channel resistance through strain-enhanced carrier mobility, the free-electron concentration saturates due to dopant compensation and the electrical resistivity increases due to increased impurity scattering. Thus, with increasing P concentration, the source and drain resistances may increase rather than decrease, which is detrimental to device performance. Furthermore, the excess donors can become deactivated upon heating during device fabrication. This is because at elevated temperatures, the surface can supply vacancies to diffuse through the nanometer-thin layer to cluster with P and form P_{N}V complexes, thereby preventing the P from being electrically active. Here, V denotes the vacancy and N=1, 2, 3, or 4. Moreover, around 700° C., low-N clusters such as P₁V and P₂V are sufficiently mobile to continue the chain reaction to deactivate more P until they become immobile high-N clusters such as P₄V.

Typical annealing technologies include rapid thermal annealing (RTA) and millisecond annealing (MSA), and may include heaters such as a flash lamp annealing tool. RTA and MSA non-selectively heat both the lattice and dopant. Commercially available microwave annealers typically use indirect heating, in which microwave energy heats a susceptor and the susceptor heats the sample. Thus, conventional microwave annealing also non-selectively heats both lattice and dopant.

### SUMMARY

According to one aspect of the disclosure, a system for selective heating of dopants or defect clusters having an electrical dipole moment includes a chamber; a heating device configured to heat a substrate borne within the chamber during system operation; a microwave source configured to direct microwave energy at a predetermined frequency to a first location within the chamber at which the substrate is disposed during the system operation; and an elongated waveguide disposed within the chamber and extending from a first end to a second end between the microwave source and the first location within the chamber, wherein the first location within the chamber at which the substrate is disposed during operation of the system is adjacent to the second end of the waveguide. In an embodiment, the substrate comprises a semiconductor doped with one or more of phosphorus, boron, arsenic, antimony, silicon, or magnesium by ion implantation or epitaxial growth.

In an embodiment, the waveguide comprises a silicon carbide coating positioned at the second end, and wherein the substrate is disposed on the silicon carbide coating during system operation. In an embodiment, the waveguide comprises a high-resistivity silicon waveguide. In an embodiment, the waveguide comprises a dielectric material having a dielectric constant that is about the same as a dielectric constant of the substrate. In an embodiment, the waveguide is shaped to output a plane wave at the first location. In an embodiment, a length of the waveguide above the microwave source is a multiple of a half wavelength of the microwave energy in the waveguide at the predetermined frequency, and wherein the waveguide is configured to provide a standing wave with maximum intensity at the second end of the waveguide. In an embodiment, a length of the waveguide below the microwave source is a quarter wavelength plus a multiple of the half wavelength of the microwave energy at the predetermined frequency, and wherein the waveguide is configured to provide a standing wave with minimum intensity at the first end of the waveguide

In an embodiment, the waveguide comprises a silicon waveguide, the system further comprising an air-cavity waveguide disposed between the microwave source and the silicon waveguide. In an embodiment, the first end of the silicon waveguide has a larger area than the second end of the silicon waveguide, and wherein the silicon waveguide comprises a tapered transition between the first end and the second end. In an embodiment, the silicon waveguide comprises a tapered inner surface extending inward from the first end toward the second end, wherein the tapered inner surface defines a tapered cavity in communication with the air-cavity waveguide.

In an embodiment, the waveguide comprises a silicon horn antenna to expand a microwave wavefront.

In an embodiment, the waveguide is characterized by a rectangular cross section. In an embodiment, the waveguide is configured to at least substantially evenly distribute the microwave energy of about 1 kV/cm across a central portion of the waveguide positioned at the second end. In an embodiment, the microwave energy may be between about 0.3 kV/cm and 1 kV/cm. In an embodiment, a standard deviation of constant power contours of microwave energy across the central portion of the waveguide at the second end is between about 5% to about 6%. In an embodiment, the standard deviation may be up to about 8% to 10%. In an embodiment, the central portion of the waveguide has dimensions of about 1 cm by 1 cm square. In an embodiment, the microwave source further comprises an electrode extending into the chamber, and wherein the electrode is received within an opening defined in a broad side of the waveguide between the first end and the second end, and wherein the electrode is positioned a multiple of a half wavelength of the microwave energy at the predetermined frequency from the second end, and wherein the electrode is positioned a quarter wavelength plus a multiple of a half wavelength of the microwave energy at the predetermined frequency from the first end, and wherein the waveguide is configured to provide a standing wave with maximum intensity at the second end of the waveguide and minimum intensity at the first end of the waveguide with the first end covered by a metal conductor. In an embodiment, the microwave source further comprises an electrode extending into the chamber, and wherein the electrode is received within an opening defined in the first end of the waveguide. In an embodiment, the rectangular cross section has a first dimension on a first and a second opposing side and a second dimension on a third and a fourth opposing side, with a ratio of the first dimension to the second dimension being about a 2:1 ratio. The first dimension is thinner than the wavelength in the waveguide and the second dimension is thinner than the half wavelength in the waveguide.

In an embodiment, the waveguide comprises an elongated waveguide extending from a first end to a second end, the waveguide comprising a bowed middle section extending from the first end to the second end and a pair of lateral extensions positioned on either side of the bowed middle section.

In an embodiment, the heating device comprises an infrared (IR) heater, a flash lamp, a near-infrared high intensity lamp, a tungsten-halogen high intensity lamp, a resistive heater, or a laser. In an embodiment, the predetermined frequency is selected from a range of available frequencies. In an embodiment, the microwave source is configured to output microwave electric field intensity of about 1 kW at a frequency of 2.45 GHz. In an embodiment, the intensity may be about 0.3 to 1 kW.

In an embodiment, the system further includes a pyrometer or a surface pyrometer configured to measure at least one of a temperature of the substrate disposed in the chamber at the first location during system operation and a temperature of the chamber during system operation. In an embodiment, the system further includes a thermocouple configured to measure a temperature of the chamber, to measure a temperature of the waveguide, or to measure a temperature of the substrate disposed in the chamber at the first location during system operation.

In an embodiment, the system further includes a controller coupled to the microwave source, the controller configured to control output of the microwave source. In an embodiment, the system further includes a controller coupled to the heating device, the controller configured to control the heating device to maintain a predetermined temperature of the substrate or to maintain a predetermined temperature in the chamber. In an embodiment, the predetermined temperature is between 300° C. to 800° C. In an embodiment, the predetermined temperature is between 650° C. to 800° C. In an embodiment, the predetermined temperature is between 700° C. to 750° C. In an embodiment, the predetermined temperature is between 650° C. to 700° C. In an embodiment, the predetermined temperature is between 670° C. to 690° C. In an embodiment, the predetermined temperature is above 800° C.

In an embodiment, the substrate comprises a 200 mm, a 300 mm, or a 450 mm silicon wafer. The silicon waveguide is scaled to accommodate the wafer size by lowering the microwave frequency and, hence, increasing the microwave wavelength. The microwave source may also be scaled according to the wafer size by increasing its output power or by an array of microwave sources spaced a half wavelength from each other. In an embodiment, the waveguide comprises a low loss material with respect to the microwave energy. In an embodiment, the waveguide comprises a metallic film coating the first end and the sidewalls of the waveguide, and wherein the metallic film has a thickness more than twice as thick as a skin depth of the microwave energy. In an embodiment, the waveguide comprises a metallic jacket enclosing the first end and the sidewalls of the waveguide, and wherein the metallic jacket has a thickness more than twice as thick as a skin depth of the microwave energy. In an embodiment, the microwave energy has an intensity of about 1 kV/cm. In an embodiment, the microwave energy may have an intensity between about 0.3 kV/cm and 1 kV/cm.

According to another aspect, a method for annealing a semiconductor substrate includes disposing a semiconductor substrate at a first location within a chamber, wherein the semiconductor substrate comprises a dopant or defect cluster having an electrical dipole moment; heating the semiconductor substrate to a predetermined temperature with a heating device; outputting microwave energy at a predetermined frequency, intensity, and period from a microwave source toward the semiconductor substrate; and passing the microwave energy at the predetermined frequency output by the microwave source through an elongated waveguide disposed within the chamber and extending from a first end to a second end between the microwave source and the first location within the chamber prior to outputting the microwave energy at the predetermined frequency toward the semiconductor substrate, wherein the microwave energy activates the dopant or breaks up the defect cluster. In an embodiment, the semiconductor substrate comprises a semiconductor doped with phosphorus arsenic, antimony, boron, or magnesium by ion implantation or epitaxial growth.

In an embodiment, heating the semiconductor substrate comprises preheating the semiconductor substrate for a predetermined duration at a predetermined heater power. In an embodiment, the method further includes heating a calibration wafer disposed at the first location within the chamber with the heating device; measuring a temperature of the calibration wafer while heating the calibration wafer; and determining the predetermined duration in response to measuring the temperature of the calibration wafer. In an embodiment, the method further includes controlling heater power while measuring the temperature of the calibration wafer; and determining the predetermined heater power in response to controlling the heater power.

In an embodiment, the waveguide comprises a silicon carbide coating positioned at the second end, and wherein disposing the substrate comprises disposing the substrate on the silicon carbide coating. In an embodiment, the waveguide comprises an air-cavity waveguide, a silicon waveguide, or a high-resistivity silicon waveguide. In an embodiment, the waveguide is shaped to output a plane wave at the first location. In an embodiment, a length of the waveguide above the microwave source is a multiple of a half wavelength of the microwave energy at the predetermined frequency, and wherein the waveguide is configured to provide a standing wave with maximum intensity at the second end of the waveguide. In an embodiment, a length of the waveguide below the microwave source is a quarter wavelength plus a multiple of a half wavelength of the microwave energy at the predetermined frequency, and wherein the waveguide is configured to provide a standing wave with minimum intensity at the first end of the waveguide.

In an embodiment, the waveguide comprises a silicon waveguide, the method further comprising an air-cavity waveguide disposed between the microwave source and the silicon waveguide. In an embodiment, the waveguide comprises a silicon horn antenna to expand a microwave wavefront

In an embodiment, the waveguide comprises an elongated waveguide extending from a first end to a second end, the waveguide comprising a rectangular cross section. In an embodiment, the waveguide is configured to evenly distribute the microwave energy across a central portion of the waveguide positioned at the second end. In an embodiment, a standard deviation of constant power contours of microwave energy across the central portion of the waveguide at the second end is between about 5% to about 6%. In an embodiment, the standard deviation may be up to about 8% to 10%. In an embodiment, the central portion of the waveguide has dimensions of about 1 cm by 1 cm square. In an embodiment, the waveguide comprises an elongated waveguide extending from a first end to a second end, the waveguide comprising a bowed middle section extending from the first end to the second end and a pair of lateral extensions positioned on either side of the bowed middle section.

In an embodiment, the heating device comprises an infrared (IR) heater, a flash lamp, a near-infrared high intensity lamp, a tungsten-halogen high intensity lamp, a resistive heater, or a laser. In an embodiment, the predetermined frequency is selected from a range of available frequencies. In an embodiment, the microwave electric field intensity at the second end of the waveguide is about 1 kV/cm and the predetermined frequency is 2.45 GHz.

In an embodiment, the method further includes measuring a temperature of the chamber via a pyrometer. In an embodiment, the method further includes measuring a temperature of the semiconductor substrate disposed in the chamber at the first location via a surface pyrometer. In an embodiment, the method further includes measuring a temperature of the chamber via a thermocouple.

In an embodiment, the method further includes controlling operation of the heating device via a controller to maintain a predetermined temperature in the chamber or to maintain a temperature in the chamber within a predetermined range of temperatures. In an embodiment, the method further includes controlling operation of the microwave source via a controller to control an output of the microwave source. In an embodiment, the predetermined temperature is between 300° C. to 800° C., between 650° C. to 800° C., between 700° C. to 750° C., between 650° C. to 700° C., or between 670° C. to 690° C. In an embodiment, the predetermined temperature is above 800° C.

In an embodiment, the substrate comprises a 200 mm, a 300 mm, or a 450 mm silicon wafer. In an embodiment, the waveguide comprises a low loss material with respect to the microwave energy. In an embodiment, the microwave energy has an intensity of about 1 kV/cm at the second end of the waveguide. In an embodiment, the microwave energy may be between about 0.3 kV/cm and 1 kV/cm. In an embodiment, outputting the microwave energy comprises outputting the microwave energy at the predetermined frequency from the microwave source toward the semiconductor substrate for a duration that is between about 4 to 6 minutes. In an embodiment, the duration may be between about 1 minute to 60 minutes.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a schematic view of at least one embodiment of a system for microwave annealing for semiconductors;

FIG. 2 is a schematic view of at least one embodiment of another system for microwave annealing for semiconductors;

FIG. 3 is a view of a silicon waveguide that may be used with the system of FIG. 2;

FIG. 4 is a schematic top view of the silicon waveguide of FIG. 3 including electric field intensity;

FIG. 5 is a schematic front view of the silicon waveguide of FIG. 3 including electric field intensity;

FIG. 6 is a schematic side view of the silicon waveguide of FIG. 3 including electric field intensity;

FIG. 7 is a view of another silicon waveguide that may be used with the system of FIG. 2;

FIG. 8 is a schematic top view of the silicon waveguide of FIG. 7 including electric field intensity;

FIG. 9 is a simplified flow diagram of at least one embodiment of a method for calibrating a system for microwave annealing that may be executed with a system of FIGS. 1-2;

FIG. 10 is a simplified flow diagram of at least one embodiment of a method for performing microwave annealing for semiconductors that may be executed with a system of FIGS. 1-2; and

FIG. 11 is a schematic view of at least one embodiment of another system for microwave annealing for semiconductors.

### DETAILED DESCRIPTION OF THE DRAWINGS

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

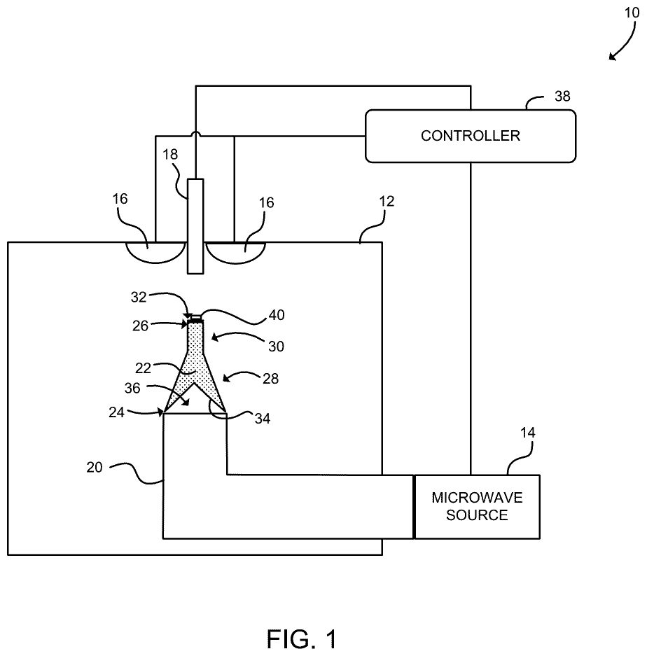

Referring now to FIG. 1, an illustrative system 10 for microwave annealing includes a chamber 12 coupled to a microwave source 14 and one or more other heating devices 16. In use, as described further below, the heating devices 16 may be used to preheat a highly doped silicon wafer or other substrate within the chamber 12. The microwave source 14 is activated, and microwave energy interacts with the electric dipole moment of dopants, vacancy clusters, and/or other defect clusters in the substrate. This interaction causes selective heating of the dopant and/or defect clusters, which activates the dopants. For example, as described above, in a silicon (Si) wafer doped with phosphorus (P), vacancies may cluster with P to form P_{N}V complexes. Such vacancies clustered with one, two, or three P atoms (e.g., P₁V, P₂V, P₃V) have a dipole moment. Vacancies with four P atoms (P₄V) are symmetrical and have no dipole moment; therefore, P₄V clusters are not activated by the microwave energy. Accordingly, the system 10 applies microwave energy to the substrate, which may release a free electron from P₁V, P₂V, or P₃V clusters, while the temperature of the nonpolar Si lattice is kept below the temperature at which new P_{N}V clusters form (e.g., 700° C.). The vacancies thus are free to diffuse to the surface of the substrate where they are annihilated. In contrast, conventional rapid thermal annealing (RTA) dissociates all vacancies non-selectively at a peak temperature and freezes unstable low-N P_{N}V clusters upon cooling. Accordingly, compared to conventional techniques such as RTA or millisecond annealing (MSA), microwave annealing as performed by the system 10 may provide more dopant activation and less dopant diffusion. Further, microwave annealing as performed by the system 10 may provide an abrupt junction profile and stable activation, particularly when the doping concentration exceeds the solubility limit of phosphorus (P), boron (B), or arsenic (As).

Additionally, as described further below, the system 10 may reliably achieve uniform microwave annealing though a solid waveguide, without moving parts such as rotating microwave deflectors or rotating sample holders, which can generate particulates due to friction to contaminate the sample.

Abrupt, stable, and high-density doping of semiconductors can be important to scaling transistors to the single nanometer size. The present disclosure provides a solution to the problem of efficient and stable dopant activation in heavily doped semiconductor wafers with an abrupt dopant profile. Compared to conventional thermal annealing, microwave annealing can directly interact with the dopant with minimal lattice heating to prevent broadening of the dopant profile and formation of unstable dopant-defect clusters.

For example, in an experiment, a 30-nm-thick Si epitaxial layer sample, doped with 3×10²¹ P/cm³ was annealed by a microwave energy of 12 kW at 2.45 GHz for 6 min using a system similar to the system 10. After microwave annealing, the sample had a free electron concentration of 4×10²⁰ cm⁻³ and a junction more abrupt than 4 decades/nm. This result is 25% more efficient than the same layer annealed by millisecond annealing (MSA) using a flash lamp. Further, the microwave annealing sample was determined to be six times more stable than the MSA sample when subjected to RTA around 700° C. for 5 min. Although the illustrative sample was annealed with microwave energy for 6 min, it should be understood that in other embodiments, microwave annealing may be performed for a different length of time and/or a different range of lengths of time, for example for about 4 min to 6 min, or from about 1 minute up to an hour, including any values therewithin or any subranges therebetween.

In addition to dopant activation in a semiconductor wafer, the microwave annealer 10 may be used to selectively break up any defect cluster with minimum lattice heating, as long as the defect cluster has an electrical dipole moment to interact directly with the microwave energy. For example, the microwave annealer 10 may be used to disinfect food or biological agents by interacting directly with the charged DNA or other protein molecules associated with viruses or other pathogens without drying the food or biological agents.

As another example, in some embodiments, the system 10 may be used for selective heating of surface atoms or dangling bonds at the surface of a substrate that have an electrical dipole moment. This selective heating may alter or eliminate surface steps on the surface of the substrate, which may obtain a smoother surface for improved epitaxial growth. As another example, in some embodiments the system 10 may be used for lattice or bulk heating of polar materials having an electrical dipole moment. For example, the system 10 may be used for bulk heating of aluminum nitride (AlN), gallium nitride (GaN), or other polar materials.

Referring again to FIG. 1, the chamber 12 may be embodied as a metallic chamber or other shielded enclosure that contains microwave energy. For example, the chamber 12 may be similar to the microwave chamber of a microwave oven. The chamber 12 may prevent leakage of microwave energy outside of the chamber 12, and may comply with one or more regulations regarding microwave energy leakage. Similarly, the microwave source 14 may be embodied as a magnetron, a traveling-wave-tube amplifier, a gyrotron, a klystron tube source, or other source of microwave energy. In the illustrative embodiment, the microwave source 14 generates microwave radiation at a predetermined frequency, such as 2.45 GHz, 5.8 GHz, or other frequency. In particular, a microwave source 14 at 2.45 GHz may take advantage of readily available, relatively inexpensive microwave generation equipment that operates in a relatively low, unlicensed frequency band. Although illustrated as generating microwave energy in unlicensed, ISM bands, it should be understood that in other embodiments the system 10 may scale to other microwave frequencies that may be more efficient for microwave annealing of certain materials.

Each of the heating sources 16 may be embodied as an infrared (IR) heater, a flash lamp, a near-infrared high intensity lamp, a tungsten-halogen high intensity lamp, a resistive heater, a laser, or other heat source capable of heating a non-polar lattice such as a silicon wafer or other semiconductor. Although illustrated as including two heating sources 16, it should be understood that in some embodiments, the system 10 may include a different number and/or arrangement of heating sources 16.

The system 10 further includes a pyrometer 18 positioned in the chamber 12. The pyrometer 18 may embodied as a pyrometer, a surface pyrometer, a thermocouple, and/or other temperature sensor capable of measuring the temperature of a semiconductor wafer or other substrate disposed in the chamber 12. Additionally or alternatively, in some embodiment, the system 10 may include a pyrometer 18, a thermocouple, or other similar temperature sensor configured to measure temperature within the waveguide 22 or the chamber 12.

As shown in FIG. 1, the system 10 includes an air-cavity waveguide 20 that couples the microwave source 14 to the interior of the chamber 12. The air-cavity waveguide 20 directs microwave energy generated by the microwave source 14 into the cavity 12. The air-cavity waveguide 20 may be, for example, a WR340 waveguide configured for transmission of microwave energy at 2.45 GHz.

The system 10 further includes a silicon waveguide 22 positioned within the chamber 12. The silicon waveguide 22 is coupled to the air-cavity waveguide 20, and is configured to direct microwave energy conveyed by the air-cavity waveguide 20 to a position in the interior of the chamber 12. As shown, the illustrative silicon waveguide 22 has an elongated body that extends from a bottom end 24, coupled to the air-cavity waveguide 20, to a top end 26. As shown, the top end 26 is narrower in cross section that the bottom end 24, and accordingly, the silicon waveguide 22 includes a tapered transition part 28 positioned at the bottom end 24 and a straight part 30 positioned at the top end 26. The top end 26 includes a silicon carbide (SiC) coating 32. As described further below, a semiconductor wafer or other substrate may be disposed on the SiC coating. The SiC coating may prevent abrasion of the waveguide 22 or wafer-waveguide welding.

The bottom end 24 of the silicon waveguide 22 is shaped to maintain a plane wave at the air-to-silicon transition between the air-cavity waveguide 20 and the silicon waveguide 20. Illustratively, the silicon waveguide 22 includes an inner wall 34 that extend inwardly from the bottom end 24 toward the top end 26. The inner wall 34 defines a transition cavity 36, which is illustratively tapered in shape. As described above, the inner wall 34 and the transition cavity 36 are shaped to maintain a plane wave at the air-to-silicon transition.

The silicon waveguide 22 may be formed from high-resistivity silicon (e.g., resistivity greater than 1 k (2/cm) other low loss material suitable for transmission of microwave energy and having a dielectric constant approximately the same as that of silicon. In an embodiment, the silicon waveguide may be machined from polycrystalline silicon. Single-crystal silicon is usually sliced from a long boule pulled from a melt of polycrystalline silicon by the Czochralski method. The growth starts with a small seed crystal, and the diameter of the boule is gradually enlarged to the desired wafer diameter. After growth, the main body of the boule with a uniform diameter is sliced into wafers. The cone-shaped seed end of the boule may be retained and machined into the silicon waveguide 22, including the necessary transition to the air-cavity waveguide 20.

The system 10 may further include a controller 38 coupled to the microwave source 14, the heating devices 16, and/or the pyrometer 18. The controller 38 which may be embodied as a microcontroller, a digital signal processor, a programmable logic unit, a computer, or any other control circuit capable of controlling operations of the microwave source 14, the heating devices 16, and/or the pyrometer 18. For example, the controller 38 may be capable of activating, deactivating, modulating, and/or otherwise controlling operation of each heating source 16 and/or the microwave source 14, and also may be capable of receiving data from or otherwise controlling operation of the pyrometer 18. To do so, the controller 38 may include a number of electronic components commonly associated with units utilized in the control of electronic and electromechanical systems. For example, the controller 38 may include, amongst other components customarily included in such devices, a processor and a memory device. The processor may be any type of device capable of executing software or firmware, such as a microcontroller, microprocessor, digital signal processor, or the like. The memory device may be embodied as one or more non-transitory, machine-readable media. The memory device is provided to store, amongst other things, instructions in the form of, for example, a software routine (or routines) which, when executed by the processor, allows the controller 38 to dynamically control the microwave source 14, the heating devices 16, and/or the pyrometer 18 using the other components of the system 10. In some embodiments, the controller 38 may also include an analog interface circuit, which may be embodied as any electrical circuit(s), component, or collection of components capable of performing the functions described herein. The analog interface circuit may, for example, convert signals from the processor into output signals which are suitable for controlling the microwave source 14, the heating devices 16, and/or the pyrometer 18. Additionally or alternatively, although illustrated in FIG. 1 as included a single controller 38, it should be understood that in some embodiments the system 10 may include additional controllers 38 and/or other control devices. For example, the system 10 may include one or more controllers 38 coupled to each of the microwave source 14 and/or the heating devices 16.

In use, as described further below, a semiconductor wafer 40 or other substrate may be placed within the chamber 12 on top the SiC coating 32 of the silicon waveguide 22. When the microwave source 14 is activated, microwave energy generated by the microwave source 14 is directed by the air-cavity waveguide 20 to the silicon waveguide 22 and, in turn, to the wafer 40. The silicon waveguide 22 may concentrate and direct the microwave energy to the wafer 40. As compared to other arrangements (e.g., sandwiching the wafer 40 between susceptors), the system 10 allows the wafer 40 to be openly placed on top of the waveguide 22. This may allow for robotic manipulation of the wafer 40 and incorporation in a cluster tool, as well as independent heating and monitoring of lattice temperature using the heating devices 16 and the pyrometer 18. Further, by the waveguide 22 being made from the same material as the sample 40, the system 10 may minimize the effect of variations in sample thickness or air-gap height (e.g., between sample 40 and the waveguide 22).

The silicon waveguide 22 may be closed along its sides with a metal jacket, preventing escape of microwave energy. The top end 26 (including the SiC coating 32) is open-ended and not covered in metal, thus allowing microwave energy to be directed at the sample 40. In an embodiment, rather than being enclosed in a metal jacket, the side walls of the semiconductor waveguide 22 may be coated with a metal layer. The thickness of the metal layer may be several times of the skin depth of the microwave.

In some embodiments, the silicon waveguide 22 may be sized or otherwise designed to generate peak standing-wave intensity at the open, top end 26 where the silicon wafer is placed. For example, the silicon waveguide 22 may have a length above the microwave source that is an integer multiple of a half wavelength of the microwave energy generated by the microwave source 14. The length below the microwave source may be a quarter wavelength plus an integer multiple of a half wavelength of the microwave energy generated by the microwave source 14. The microwave energy may have an electrical field intensity at the top end 26 of about 1 kV/cm, about 0.75 kV/cm, or in some embodiments may have electric field intensity in the range of 300 V/cm to 1 kV/cm, including any values therewithin or any subranges therebetween.

Although illustrated as a silicon waveguide 22 that concentrates microwave energy, in other embodiments the system 10 may include a silicon horn antenna or other waveguide that expands the microwave wave-front. The expanded wave-front may accommodate larger-sized wafers 40 or otherwise accommodate larger substrates. Additionally or alternatively, the system 10 may scale to larger wafers by using lower-frequency microwave and correspondingly larger silicon waveguides. For example, scaling the frequency from 2.45 GHz to the 13.553-13.567 MHZ ISM band may increase the sample area from 1 cm×1 cm to approximately 6′×6′. In some embodiments, the predetermined frequency is selected in a range of 10 MHz to 10 GHz, including any values therewithin or any subranges therebetween, depending on the physical parameters of the system or device such as the sample area, and/or a wafer size. In some embodiments, the wafer (e.g., a silicon wafer) has a predetermined diameter in a range of about 25 mm to about 500 mm, including any values therewithin or any subranges therebetween, preferably a diameter in a range of about 200 mm to about 450 mm

Additionally or alternatively, although described as a silicon waveguide 22, in other embodiments the waveguide 22 may be formed from a different material that matches the dielectric properties of the substrate, for example when operating on semiconductors having dielectric properties that differ significantly from silicon. In each embodiment, the waveguide 22 may be formed from a material that is low loss for microwave.

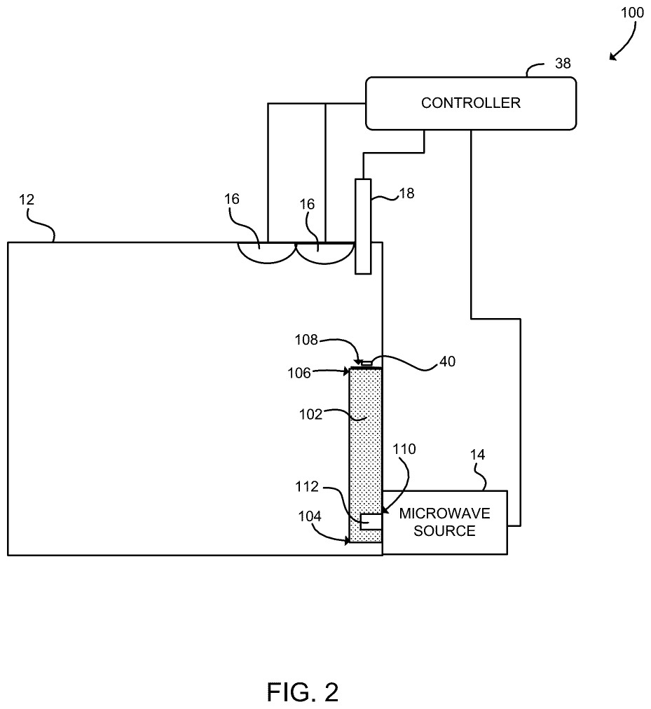

Referring now to FIGS. 2-6, another illustrative system 100 for microwave annealing is shown. Similar to the system 10, the system 100 includes a chamber 12, a microwave source 14, heating devices 16, a pyrometer 18, and a controller 38. The description of each of those components is similar to the corresponding components of the system 10 and is not repeated herein so as not to obscure the present disclosure.

As shown in FIGS. 2-6, the system 100 further includes a silicon waveguide 102 positioned in the chamber 12. Similar to the silicon waveguide 22, the waveguide 102 may be machined or otherwise formed from high-resistivity silicon. The waveguide 102 extends from a bottom end 104 to a top end 106, and includes a silicon carbide (SiC) coating 108 covering the top end 106. Similar to the waveguide 22, in use a wafer 40 or other substrate is positioned on the coating 108, and the waveguide 102 directs microwave energy to the wafer 40.

The waveguide 102 further includes an opening 110 positioned on a side. The opening 110 is sized to receive an antenna 112 that is coupled to the microwave source 14. As described further below, the antenna 112 couples microwave energy from the microwave source 14 to the waveguide 102.

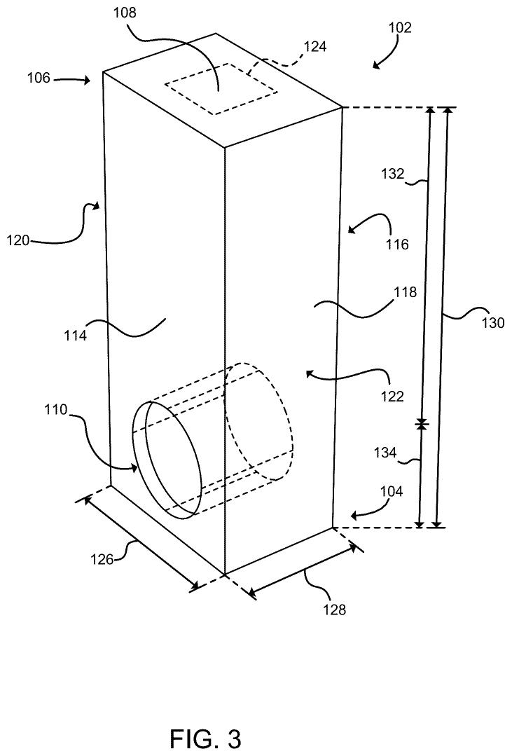

As best shown in FIGS. 3-6, the waveguide 102 has a rectangular cross-section, with a pair of opposing sides 114, 116 and another pair of smaller opposing sides 118, 120. The waveguide 102 may further include a metallic jacket 122 or metallic coating 122 that covers the sides 114, 116, 118, 120, along with the bottom end 104. The top end 106, coated by the SiC coating 108, is not covered by the metallic jacket 122. A central area 124 is defined on the top end 106, which in the illustrative embodiment is about 1 cm square.

As shown, each side 114, 116 has a dimension 126 (e.g., length or width), and each side 118, 120 similarly has a dimension 128. The dimension 126 is roughly twice the dimension 128. In particular, the dimension 126 may be thinner than the wavelength of the microwave radiation in the waveguide 102 and the dimension 128 may be thinner than a half-wavelength of the microwave radiation in the waveguide 102, which may ensure single mode wave propagation in the waveguide 102. In an illustrative embodiment, the dimension 126 may be 2.54 cm (or 1 in), and the dimension 128 may be 1.78 cm (or 0.7 in) for a predetermined microwave frequency of 2.45 GHz. The waveguide 102 further includes a height 130, which in the illustrative embodiment may be 6.20 cm (or 2.44 in). The center of the opening 110 (and thus the center of the antenna 112 when inserted in the opening 110) is positioned at a distance 132 below the top end 106 and a distance 134 above the bottom end 104. In the illustrative embodiment, the distance 132 may be 5.11 cm (or 2.01 in) and the distance 134 may be 1.09 cm (or 0.43 in). As described above, the system 100 may scale by using lower-frequency microwave energy and correspondingly larger silicon waveguides 102. For example, scaling the frequency from 2.45 GHz to the 13.553-13.567 MHz ISM band may increase the central area 124 from 1 cm×1 cm to approximately 6′×6′ and may scale the other dimensions 126, 128, 130 similarly, including any values therewithin or any subranges therebetween.

Also similar to the waveguide 22 described above, the silicon waveguide 102 may be sized or otherwise designed to generate peak standing-wave intensity at the open, top end 106 where the silicon wafer is placed. For example, the waveguide 102 is configured to take advantage of standing waves established by reflecting the microwave energy from both the top 106 and the bottom 104 of the silicon waveguide 102, which are open to air and covered by metal, respectively. In microwave terminology, these resemble OPEN and SHORT terminations, respectively, where the microwave is completely reflected. The only difference is that the microwave reflected from OPEN has the same phase as the incident wave has, whereas the microwave reflected from SHORT is 180° out of phase from the incident wave. Therefore, the microwave amplitude is maximized at OPEN and minimized at SHORT. In the illustrative embodiment, the antenna 112 from the microwave source 14 is inserted approximately an integer multiple of one half-wavelength of the microwave energy in silicon (Nλ_{Si}/2) below the top 106 of the silicon waveguide 102. The antenna 102 is similarly placed (2N+1)_{λSi}/4 above the bottom 104 of the silicon waveguide 102, where N is an integer. This forms a standing wave in the silicon waveguide 102 with maximum magnitude at the top 106 and minimum magnitude at the bottom 104.

Additionally or alternatively, in some embodiments, total power of the system 10 may be boosted by coupling multiple microwave sources 14 to the waveguide 102. In an embodiment, each of the sources 14 may be arrayed at a separation of λ_{Si}/2 from each other, so that the power from each microwave source 14 is added constructively

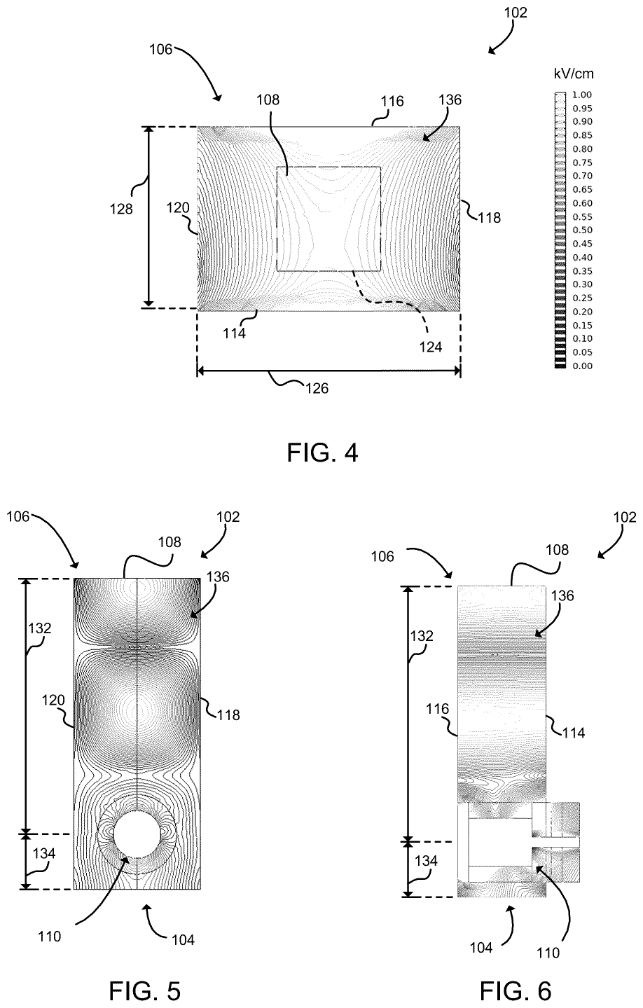

The waveguide 102 may be further configured to provide roughly uniform field strength (e.g., electric or magnetic field strength) for microwave energy at the top end 106 where the wafer 40 or other substrate is positioned. As best shown in FIGS. 4-6, microwave energy transmitted through the waveguide 102 may be illustrated as multiple constant-field contour lines 136. As shown, in the central area 124 of the illustrative waveguide 102, the microwave field strength is roughly constant. For example, in an illustrative embodiment, the electric field strength over the central area is 0.75 kV/cm±5.5%. In some embodiments, the electric field strength may vary over the central area by a range of percentages, for example up to 8% to 10%, including any values therewithin or any subranges therebetween. The sample 40 may be placed over the central area 124 of the waveguide 102, providing uniform microwave energy transfer to the sample 40.

Referring again to FIGS. 2-6, a transverse electromagnetic wave from the microwave source 14 may be efficiently converted to the transverse electric wave in the rectangular silicon waveguide 102 by inserting the antenna 112 of the microwave source 14 from a broad side 114, 116 of the silicon waveguide 102. Additionally or alternatively, in other embodiments the antenna 112 may be coupled to the waveguide 102 in a different arrangement. For example, in an embodiment (not illustrated), the antenna 112 may be received by an opening 110 formed in the bottom 104 of the waveguide 102. In that embodiment, the waveguide 102 may have a height 130 that is an integer multiple of one half-wavelength of the microwave energy in silicon (Nλ_{Si}/2), which may form a standing wave with maximum intensity at the top end 106.

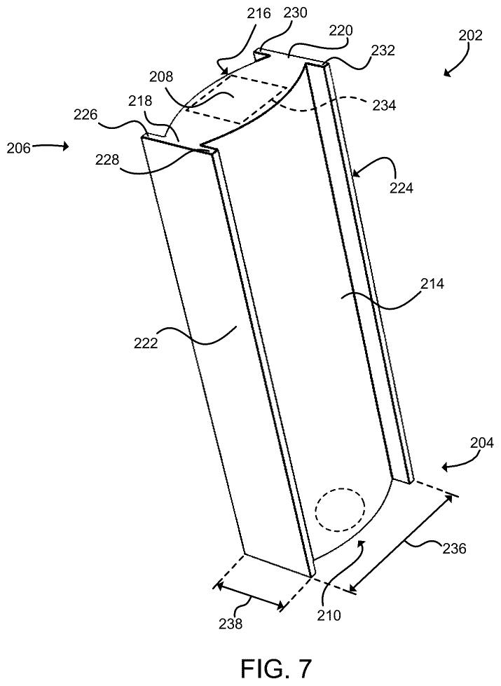

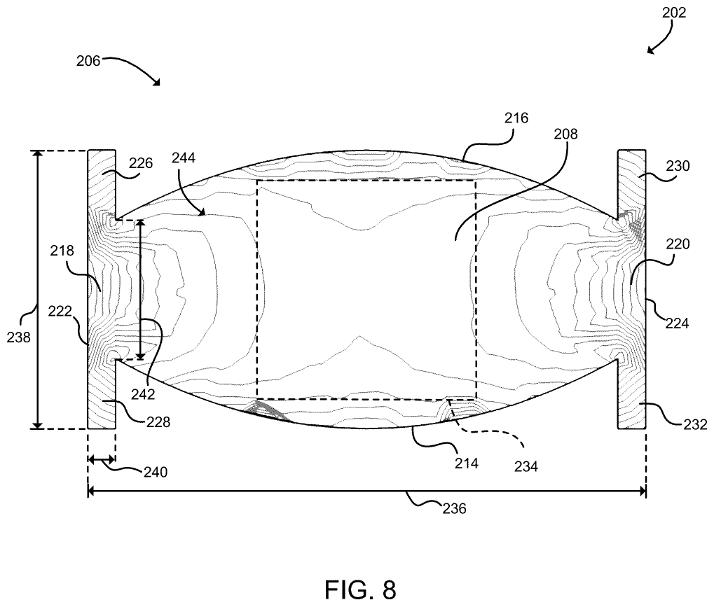

Referring now to FIGS. 7-8, another potential embodiment of a silicon waveguide 202 may be used with the system 10, 100. Similar to the silicon waveguide 22, 102, the waveguide 202 may be machined or otherwise formed from high-resistivity silicon. The waveguide 202 extends from a bottom end 204 to a top end 206, and includes a silicon carbide (SiC) coating 208 covering the top end 206. Similar to the waveguide 22, 102, in use a wafer 40 or other substrate is positioned on the coating 208, and the waveguide 202 directs microwave energy to the wafer 40.

The waveguide 202 further includes an opening 210 positioned on the bottom end 204. The opening 210 is sized to receive an antenna 112 that is coupled to the microwave source 14. As described further below, the antenna 112 couples microwave energy from the microwave source 14 to the waveguide 202. The waveguide 202 may have a length between the bottom end 204 and the top end 206 that is an integer multiple of one half-wavelength of the microwave energy in silicon (Nλ_{Si}/2), which may form a standing wave with maximum intensity at the top end 206.

The waveguide 202 may be further configured to provide roughly uniform field strength (e.g., electric or magnetic field strength) for microwave energy at the top end 206 where the wafer 40 or other substrate is positioned. As shown, the waveguide 202 includes a pair of opposing, bowed sides 214, 216 that extend from the bottom end 204 to the top end 206. Each of the bowed sides 214, 216 has a curved surface having a Gaussian shape. Other embodiments may have a different shape, such as a sinusoidal shape.

The bowed sides 214, 216 extend outwardly along the middle of the waveguide 202 and curve inward toward lateral sides of the waveguide 202. A pair of lateral extensions 218, 220 are positioned on either of the narrow, lateral sides of the bowed sides 214, 216. Each lateral extension 218, 220 has a flat side 222, 224, respectively. As shown, the lateral extension 218 includes a pair of ribs 226, 228 that extend along the flat side 222 and away from the bowed sides 214, 216. Similarly, the lateral extension 220 includes a pair of ribs 230, 232 that extend along the flat side 224 and away from the bowed sides 214, 216.

A central area 234 is defined on the top end 206 of the waveguide 202, and the waveguide 202 has dimensions 236, 238. As shown, the waveguide 202 has a roughly rectangular cross-section, and the dimension 236 is roughly twice the dimension 238. In an illustrative embodiment, the dimension 236 may be 2.54 cm (or 1 in), and the dimension 238 may be 1.27 cm (or 0.5 in) for a predetermined microwave frequency of 2.45 GHz. The central area 234 may be about 1 cm square. Continuing that example, in an embodiment, each of the lateral extensions 218, 220 has a rib thickness 240 of 0.13 cm, and the waveguide 202 has a minimum thickness 242 where the lateral extensions 218, 220 meet the bowed sides 214, 216 of 0.7 cm.

As best shown in FIG. 8, microwave energy transmitted through the waveguide 202 may be illustrated as multiple constant-field contour lines 244. As shown, in the central area 234 of the illustrative waveguide 202, the microwave field strength is roughly constant. For example, in an illustrative embodiment, the electric field strength over the central area is 309 V/cm±4%. The sample 40 may be placed over the central area 234 of the waveguide 202, providing uniform microwave energy transfer to the sample 40.

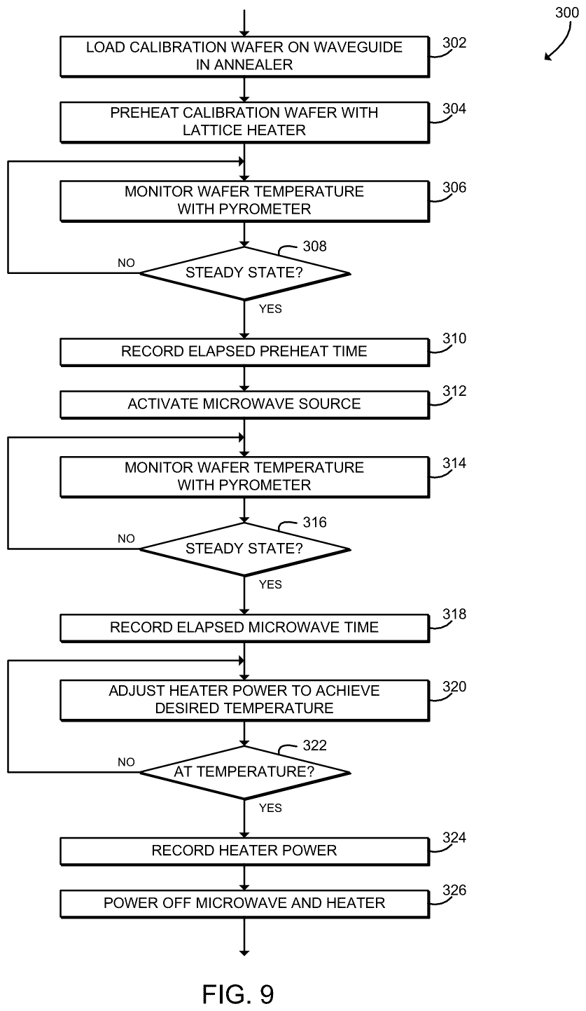

Referring now to FIG. 9, a method 300 may be used for calibrating the system 10, 100. It should be appreciated that, in some embodiments, one or more operations of the method 300 may be performed by the controller 38 and/or other components of the system 10, 100 as shown in FIGS. 1-8. The method 300 begins in block 302, in which a calibration wafer is loaded on the waveguide 22, 102, 202 in the chamber 12 of the microwave annealer system 10, 100. The calibration wafer has the same resistivity and thickness as the substrate upon which the doped silicon layer is grown. The calibration wafer is placed on the SiC coating 32, 108, 208 positioned on the top end 26, 106, 206 of the respective waveguide 22, 102, 202.

In block 304, the heating devices 16 are activated to preheat the calibration wafer. The heating devices 16 may be activated or otherwise controlled by the controller 38. Preheating causes heating in the nonpolar, silicon lattice of the calibration wafer. In block 306, temperature of the calibration wafer is monitored with the pyrometer 18. For example, the controller 38 may monitor sensor data generated by the pyrometer 18 or otherwise monitor temperature of the calibration wafer. In block 308, it is determined whether temperature of the calibration wafer has reached a steady state temperature, such as 500° C. If not, the method 300 loops back to block 306 in which the controller 38 continues to monitor temperature of the calibration wafer. If the calibration wafer has reached the steady state temperature, the method 300 advances to block 310, in which the elapsed preheating time required to reach the steady state temperature is recorded.

In block 312, the microwave source 14 is activated. The microwave source 14 may be activated or otherwise controlled by the controller 38. As described above, activating the microwave source 14 causes microwave energy to be transferred through the waveguide 22, 102, 202 and directed at the calibration wafer. In block 314, the surface temperature of the calibration wafer is monitored with the pyrometer 18. For example, the controller 38 may monitor sensor data generated by the pyrometer 18 or otherwise monitor temperature of the calibration wafer. In block 316, it is determined whether the temperature of the calibration wafer has reached a steady state. If not, the method 300 loops back to block 314 in which the controller 38 continues to monitor wafer temperature with both the heating devices 16 and the microwave source 14 active. If the calibration wafer has reached the steady state temperature, the method 300 advances to block 318, in which the elapsed microwave time required to reach the steady state temperature is recorded.

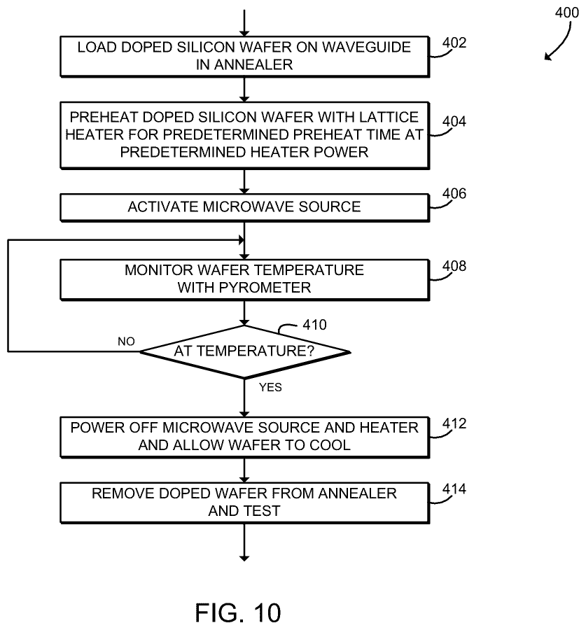

In block 320, the heating power of the heating devices 16 is adjusted to achieve a desired temperature, such as 700° C. The controller 38 may, for example, control heater power of the heating devices 16 while monitoring surface temperature of the calibration wafer using the pyrometer 18. In some embodiments, power of the heating devices 16 may be adjusted to achieve a temperature within a range of desired temperatures, such as between 300° C. to 800° C., between 650° C. to 800° C., between 700° C. to 750° C., between 650° C. to 700° C., between 670° C. to 690° C., or above 800° C., including any values therewithin or any subranges therebetween. In block 322, it is determined whether the calibration wafer has reached the desired temperature. If not, the method 300 loops back to block 320 to continue adjusting heating power of the heating devices 16. If the calibration wafer has reached the desired temperature, the method 300 advances to block 324, in which the heating power of the heating devices 16 is recorded. In block 326, the microwave source 14 and the heating devices 16 are powered off and the calibration wafer is allowed to cool, for example to 100° C. After cooling, the calibration wafer may be removed from the chamber 12 and the method 300 is completed. After completing calibration, the system 10, 100 may be used for microwave annealing as described below in connection with FIG. 10.

Referring now to FIG. 10, a method 400 may be used for performing microwave annealing with the system 10, 100. It should be appreciated that, in some embodiments, one or more operations of the method 400 may be performed by the controller 38 and/or other components of the system 10, 100 as shown in FIGS. 1-8. The method 400 may be executed after performing calibration as described above in connection with the method shown in FIG. 9. The method 400 begins in block 402, in which a doped semiconductor wafer 40 is loaded on the waveguide 22, 102, 202 in the chamber 12 of the microwave annealer system 10, 100. The doped wafer 40 may be embodied as highly doped silicon (e.g., Si doped with P) that is created by ion implantation or epitaxial growth. Although described as a wafer 40, it should be understood that the chamber 12 may be loaded with any appropriate size and/or shape of doped semiconductor substrate. For example, in an embodiment, the chamber 12 may be loaded with a 1 cm square coupon diced from a full silicon wafer. The doped wafer 40 is placed on the SiC coating 32, 108, 208 positioned on the top end 26, 106, 206 of the respective waveguide 22, 102, 202.

In block 404, the doped silicon wafer 40 is preheated with the lattice heating devices 16 for a predetermined preheat time at a predetermined heater power. The heating devices 16 may be activated or otherwise controlled by the controller 38, and the preheat time and the heater power may be determined in connection with a calibration process such as the method 300 shown in FIG. 9 and described above. Continuing that example, the preheat time may be previously determined as described above in connection with block 310, and the heater power may be previously determined as described above in connection with block 324.

In block 406, the microwave source 14 is activated. The microwave source 14 may be activated or otherwise controlled by the controller 38. As described above, activating the microwave source 14 causes microwave energy to be transferred through the waveguide 22, 102, 202 and directed at the doped silicon wafer 40. The microwave energy interacts with the electrical dipole moment of dopants and/or defect clusters within the doped silicon wafer 40, which causes selective heating of those dopants and/or defect clusters. In block 408, the surface temperature of the doped wafer 40 is monitored with the pyrometer 18. For example, the controller 38 may monitor sensor data generated by the pyrometer 18 or otherwise monitor temperature of the doped wafer 40. In block 410, it is determined whether the doped wafer 40 has reached a desired temperature, such as 700° C. In some embodiments, it may be determined whether the doped wafer 40 has reached a temperature within a range of desired temperatures, such as between 300° C. to 800° C., between 650° C. to 800° C., between 700° C. to 750° C., between 650° C. to 700° C., between 670° C. to 690° C., or above 800° C., including any values therewithin or any subranges therebetween. If not, the method 400 loops back to block 408, in which the temperature of the doped wafer 40 continues to be monitored while the heating devices 16 and the microwave source 14 are active. If the doped wafer has reached the predetermined temperature, the method 400 advances to block 412.

In block 412, the microwave source 14 and the heating devices 16 are powered off, and the doped wafer 40 is allowed to cool, for example to a temperature of 100° C. After cooling, in block 414 the doped wafer 40 is removed from the chamber 12 and may be tested. For example, a 4-probe measurement may be performed to confirm that sheet resistivity of the doped wafer 40 is minimized. If not, the method 400 may be repeated with another doped wafer 40 until sheet resistivity is minimized. Microwave power and/or time may be reoptimized for different types, concentrations, and/or growth methods of dopants.

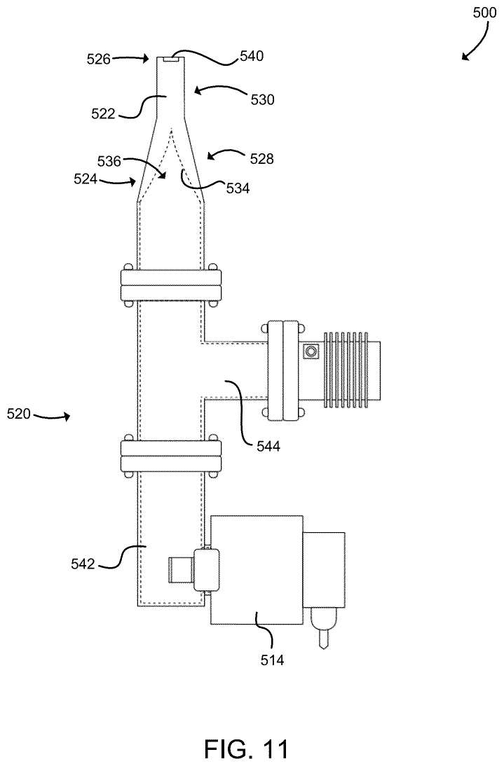

Referring now to FIG. 11, an illustrative system 500 for microwave annealing includes a microwave source 514 such as a magnetron. The microwave source 514 is coupled to an air-cavity waveguide 520 and a dielectric waveguide 522. The illustrative dielectric waveguide 522 has an elongated body that extends from a bottom end 524, coupled to the air-cavity waveguide 520, to a top end 526. As shown, the top end 526 is narrower in cross section that the bottom end 524, and accordingly, the dielectric waveguide 522 includes a tapered transition part 528 positioned at the bottom end 524 and a straight part 530 positioned at the top end 526. A sample 540 may be positioned in a recess at the top end 526 of the dielectric waveguide 522. The dielectric waveguide 522 is formed of a dielectric material having the same dielectric properties as the sample 540. For example, in some embodiments the dielectric waveguide 522 may be formed from silicon.

As shown, the air-cavity waveguide 520 further includes a launcher 542, coupled to the microwave source 514. The launcher 542 is a waveguide section that converts a transverse electromagnetic (TEM) wave from the microwave source 514 to a transverse electric (TE) wave in the waveguide 520. The air-cavity waveguide 520 further includes a circulator 544 positioned between the launcher 542 and the dielectric waveguide 522. The circulator 544 allows microwave energy to be transmitted forward from the microwave source 514 to the dielectric waveguide 522 and blocks reflected microwave energy from the dielectric waveguide 522, thereby preventing transmission of microwave energy from the dielectric waveguide 522 to the microwave source 514. The circulator 544 thus may protect the microwave source 514 from potential damage caused by reflected microwave energy.

1. A system for selective activation of dopants or defect clusters having an electrical dipole moment, the system comprising:
a chamber;
an activation device configured to activate a substrate borne within the chamber during system operation;
a microwave source configured to direct microwave energy at a predetermined frequency to a first location within the chamber at which the substrate is disposed during the system operation; and
an elongated waveguide disposed within the chamber and extending from a first end to a second end between the microwave source and the first location within the chamber, wherein the first location within the chamber at which the substrate is disposed during operation of the system is adjacent to the second end of the waveguide, and the waveguide comprises a dielectric waveguide and an air-cavity waveguide disposed between the microwave source and the dielectric waveguide, wherein the first end of the dielectric waveguide has a larger area than the second end of the dielectric waveguide, and wherein the dielectric waveguide comprises a tapered transition between the first end and the second end.

2. The system of claim 1, wherein the substrate comprises a semiconductor doped with one or more of phosphorus, boron, arsenic, antimony, silicon, or magnesium by ion implantation or epitaxial growth.

3-4. (canceled)

5. The system of claim 1, wherein the dielectric waveguide comprises a dielectric material having a dielectric constant that is about the same as a dielectric constant of the substrate.

6. (canceled)

7. The system of claim 1, wherein a length of the waveguide above the microwave source is a multiple of a half wavelength of the microwave energy at the predetermined frequency, and wherein the waveguide is configured to provide a standing wave with maximum intensity at the second end of the waveguide.

8-10. (canceled)

11. The system of claim 1, wherein the dielectric waveguide comprises a tapered inner surface extending inward from the first end toward the second end, wherein the tapered inner surface defines a tapered cavity in communication with the air-cavity waveguide.

12-13. (canceled)

14. The system of claim 1, wherein the waveguide is configured to at least substantially evenly distribute the microwave energy across a central portion of the waveguide positioned at the second end.

15-22. (canceled)

23. The system of claim 1, wherein the microwave energy is supplemented by a heating device comprising an infrared (IR) heater, a flash lamp, a near-infrared high intensity lamp, a tungsten-halogen high intensity lamp, a resistive heater, or a laser.

24-25. (canceled)

26. The system of claim 1, further comprising a pyrometer or a surface pyrometer configured to measure at least one of a temperature of the substrate disposed in the chamber at the first location during system operation, a temperature of the waveguide, and a temperature of the chamber during system operation.

27. The system of claim 1, further comprising a thermocouple configured to measure a temperature of the chamber, to measure a temperature of the waveguide, or to measure a temperature of the substrate disposed in the chamber at the first location during system operation.

28-36. (canceled)

37. The system of claim 1, wherein the dielectric waveguide comprises a low loss material with respect to the microwave energy having a dielectric constant about the same as that of the substrate.

38. The system of claim 1, wherein the waveguide comprises a metallic film coating the first end and sidewalls of the waveguide or a metallic jacket enclosing the first end and sidewalls of the waveguide, and wherein the metallic film or the metallic jacket has a thickness more than twice as thick as a skin depth of the microwave energy.

39-40. (canceled)

41. A method for dopant activation in a semiconductor substrate by using a system of claim 1, comprising:
disposing a semiconductor substrate at a first location within the chamber, wherein the semiconductor substrate comprises a dopant or defect cluster having an electrical dipole moment;
heating the semiconductor substrate to a predetermined temperature with a heating device;
outputting microwave energy at a predetermined frequency from the microwave source toward the semiconductor substrate; and
passing the microwave energy at the predetermined frequency output by the microwave source through an elongated waveguide disposed within the chamber and extending from a first end to a second end between the microwave source and the first location within the chamber prior to outputting the microwave energy at the predetermined frequency toward the semiconductor substrate, wherein the microwave energy activates the dopant or breaks up the defect cluster.

42-44. (canceled)

45. The method of claim 41, wherein the semiconductor substrate comprises a semiconductor doped with phosphorus arsenic, antimony, boron or magnesium by ion implantation or epitaxial growth.

46-48. (canceled)

49. The method of claim 41, wherein a length of the waveguide above the microwave source is a multiple of a half wavelength of the microwave energy at the predetermined frequency, and wherein the waveguide is configured to provide a standing wave with maximum intensity at the second end of the waveguide.

50. The method of claim 41, wherein a length of the waveguide below the microwave source is a quarter wavelength plus a multiple of a half wavelength of the microwave energy at the predetermined frequency, and wherein the waveguide is configured to provide a standing wave with minimum intensity at the first end of the waveguide.

51. The method of claim 41, wherein the waveguide comprises a silicon waveguide, the method further comprising an air-cavity waveguide disposed between the microwave source and the silicon waveguide.

52. (canceled)

53. The method of claim 41, wherein the waveguide is configured to evenly distribute the microwave energy across a central portion of the waveguide positioned at the second end.

54-56. (canceled)

57. The method of claim 41, wherein the microwave energy is supplemented by a heating device comprising an infrared (IR) heater, a flash lamp, a near-infrared high intensity lamp, a tungsten-halogen high intensity lamp, a resistive heater, or a laser.

58-71. (canceled)

72. The system of claim 1, further comprising a circulator between the microwave source and the dielectric waveguide, wherein the circulator is configured to allow microwave transmitting from the microwave source to the dielectric waveguide and block the microwave reflected from the dielectric waveguide back to the microwave source.

73. The system of claim 72, further comprising a launcher between the circulator and the microwave source, wherein the launcher is configured to convert the transverse electromagnetic (TEM) wave from the source to the Transverse electric (TE) wave in the waveguide.
